(19) United States
(12) Patent Application Publication
(10) Pub. No.: US 2009/0121341 A1
(43) Pub. Date: May 14, 2009

(54) COMPONENT FOR SEMICONDUCTOR PACKAGE AND MANUFACTURING METHOD OF COMPONENT FOR SEMICONDUCTOR PACKAGE

(75) Inventors: Kiyoshi Oi, Nagano-shi (JP); Teruaki Chino, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/265,191

(22) Filed: Nov. 5, 2008

(30) Foreign Application Priority Data
Nov. 8, 2007 (JP) 2007-290706

(51) Int. Cl. H01L 23/12; H01L 21/00

(52) U.S. Cl. 257/701; 438/125; 257/E23.003

(57) ABSTRACT

A component for semiconductor package which has a protective insulating layer on at least one surface of a component body and exposes a conductive material of the component body to an opening part of the protective insulating layer is manufactured by a method including the steps of (a) forming a mask on at least one surface of the component body, (b) forming the protective insulating layer by filling an opening part of the mask with a protective insulating material by a molding method using a metal mold comprising a mold release film, and (c) removing the metal mold and removing the mask. A typical component is a lead frame or a substrate for semiconductor package.

### TECHNICAL FIELD

The present disclosure relates to a component for semiconductor package and a manufacturing method of the component for semiconductor package. Particularly, the present disclosure relates to a component such as a lead frame for semiconductor package or a substrate for semiconductor package used in the case of mounting a semiconductor chip in a mounting substrate, and a manufacturing method of such a component.

### RELATED ART

In the case of mounting a semiconductor chip, a component for installing the chip and mounting the chip in a mounting substrate is used. For example, a technique for installing a semiconductor chip in a mounting substrate using a semiconductor package fabricated by installing the semiconductor chip in a substrate for package is widely used.

A related-art substrate for semiconductor package is generally fabricated as a wiring substrate in which multilayer wiring is formed in an organic core substrate by a build-up method. A semiconductor chip is installed on one surface of such a substrate for semiconductor package by ball grid array (BGA) connection etc. and a terminal (a solder bump etc.) for external connection for making connection to a mounting substrate such as a motherboard is disposed on the other surface of the substrate. Also, a solder resist layer is normally disposed as a protective insulating layer excluding the portion of the terminal for external connection and a connection part to the semiconductor chip on both surfaces of the semiconductor package.

In manufacture of a related-art semiconductor package, a solder resist layer is generally formed by a method for patterning a photosensitive solder resist material or a method for printing a nonphotosensitive solder resist material.

In the method for patterning the photosensitive solder resist material, solder resist material layers 103 are formed on wiring layers 102 of the outermost layer formed on both sides of a wiring substrate 101 as shown in FIG. 7A. Subsequently, the solder resist material layers 103 are exposed using a photomask 104 (the photomask 104 is illustrated in only the upper surface side for the sake of simplicity in FIG. 7A). After the exposure, the photosensitized portion (for a positive resist) of the solder resist material layers 103 and the photomask 104 are removed and as shown in FIG. 7B, patterned solder resist layers 106 are formed (the solder resist layers formed on both upper and lower surfaces are shown in FIG. 7B).

In the printing method, as shown in FIG. 8A, solder resist materials are printed using masks 113 arranged on a wiring substrate 111 in which wiring layers 112 of the outermost layer are formed on both sides, and solder resist materials 114 are arranged in opening parts of the masks 113 and thereafter, the masks 113 are removed and the solder resist materials 114 are cured and then, solder resist layers 115 of predetermined patterns are formed as shown in FIG. 8B.

The photosensitive solder resist material is inevitable that a substance for expressing photosensitivity is included. Such a substance is regarded as a certain kind of impurity to the solder resist material. As a result of that, reliability of the solder resist layer formed may become a problem in the case of the patterning method using the photosensitive solder resist material.

In the printing method, use of a mask is indispensable. With increasing miniaturization of an electronic component including a semiconductor chip, a printed pattern also becomes finer and it becomes difficult to form a fine pattern with high accuracy in the printing method using the mask.

### SUMMARY

Exemplary embodiments of the present invention provide a component for semiconductor package comprising a protective insulating layer of a high-accuracy fine pattern which cannot be formed in a printing method and is manufactured using a protective insulating material (in other words, a nonphotosensitive protective insulating material) without including a photosensitive expression substance which may decrease reliability of a solder resist layer formed, and a manufacturing method of such a component for semiconductor package.

A manufacturing method of a component for semiconductor package of the invention is a manufacturing method of a component for semiconductor package which has a protective insulating layer on at least one surface of a component body and exposes a conductive material of the component body to an opening part of the protective insulating layer, steps of: (a) forming a mask on at least one surface of a component body, the mask having an opening part; (b) forming a protective insulating layer by filling the opening part of the mask with a protective insulating material by a molding method using a metal mold having a mold release film; and (c) removing the metal mold and removing the mask.

The mask can be formed by a resist or a metal material. In the case of the resist material, for example, a photosensitive film also called a “dry resist film” can be used.

A transfer molding method for supplying a melted thermosetting resin to a cavity and curing the resin is preferably used as the molding method.

As the component body, for example, a wiring substrate or a lead frame before the protective insulating layer is formed on at least one surface can be given.

A component for semiconductor package of the invention is a component for semiconductor package comprising a component body; a protective insulating layer formed on at least one surface of the component body and formed by a nonphotosensitive resin, the protective insulating layer has an opening part; and an external connection terminal disposed in the opening part of the protective insulating layer.

According to the invention, a component for semiconductor package comprising a highly-reliable protective insulating film of a fine pattern indispensable for high-density mounting formed with high accuracy without using a printing method and without using a solder resist material including a photosensitive expression substance can be provided.

Other features and advantages may be apparent from the following detailed description, the accompanying drawings and the claims.

### BRIEF DESCRIPTION OF THE DRAWINGS

FIGS. 1A to 1E are views schematically describing a step of manufacturing a substrate for semiconductor package according to the invention.

FIGS. 2A to 2E are views schematically describing a step of manufacturing a lead frame for semiconductor package according to the invention.

FIGS. 3A and 3B are schematic views describing a semiconductor package obtained by installing a semiconductor chip on a substrate for semiconductor package according to the invention.

FIG. 4 is a schematic view showing a motherboard on which the semiconductor package of FIG. 3A is mounted.

FIGS. 5A and 5B are schematic views describing a semiconductor package obtained by installing a semiconductor chip on a lead frame for semiconductor package according to the invention.

FIG. 6 is a schematic view showing a motherboard on which the semiconductor package of FIG. 5A is mounted.

FIGS. 7A and 7B are schematic views describing manufacture of a substrate for semiconductor package according to a related-art method for patterning a photosensitive solder resist material.

FIGS. 8A and 8B are schematic views describing manufacture of a substrate for semiconductor package according to a related-art method for printing a solder resist material.

### DETAILED DESCRIPTION

A component for semiconductor package manufactured by a method of the invention is a component used for fabricating a semiconductor package used for installing a semiconductor chip and mounting the semiconductor chip on a mounting substrate etc., and a wiring substrate (generally, an organic substrate in which a predetermined number of wiring layers are formed) or a lead frame are typical.

A “component body” in a manufacturing method of the component for semiconductor package of the invention refers to a semi-finished product before a protective insulating film for exposing a part of the wiring layer is formed, the semi-finished product having a wiring layer formed by a conductive material on at least one surface. A typical example of such a component body is a wiring substrate before a protective insulating layer is formed on at least one side, the wiring substrate having a wiring layer on at least one surface (may have one or more wiring layers in the inside or may have a wiring layer on the opposite surface as long as the wiring substrate has a wiring layer on at least one surface) or a lead frame before a protective insulating layer is formed on at least one side.

A manufacturing method of the component for semiconductor package of the invention will hereinafter be described in further detail with reference to the drawings.

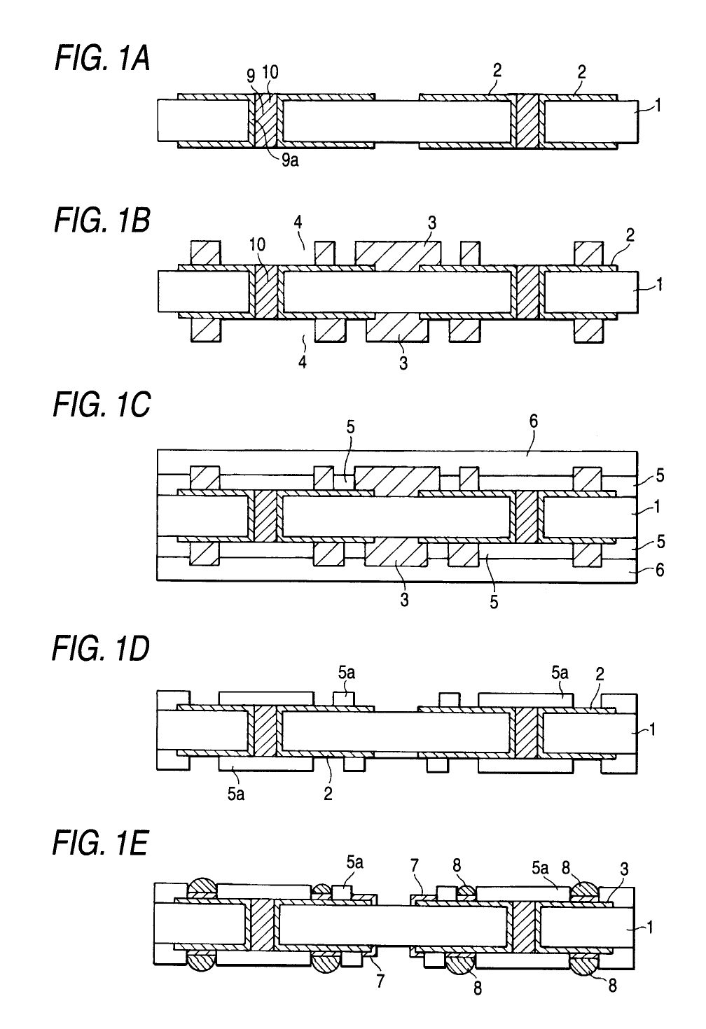

In the case of a substrate for package, a wiring substrate body 1 in which wiring layers 2 of the outermost layer are formed on both sides is fabricated as shown in FIG. 1A. The wiring substrate body 1 is generally fabricated by forming a predetermined number of wiring layers on both surfaces of a core material (a composite material in which a glass cloth etc. are impregnated with a resin) by a build-up method, and the wiring layers of both surfaces are communicated by a conductive film 9a formed on an inner wall of a through hole 9 of the substrate body 1. After the conductive film 9a is formed, the through hole 9 is filled with an epoxy resin 10 and is planarized by polishing etc. With respect to the substrate 1, only the through hole 9 filled with the epoxy resin 10 and the wiring layers 2 of the outermost layer are shown in the reference drawings herein including FIG. 1A for the sake of simplicity.

Next, as shown in FIG. 1B, resist materials arranged on the wiring layers 2 are patterned and resist masks 3 are formed. As the resist material, for example, a photosensitive film (as one example, a photosensitive film called a “dry resist film”) can be used. In the case of using the photosensitive film, the photosensitive film can be patterned by exposure and development after the photosensitive film is stuck on the wiring layers 2 of the outermost layer.

After the resist masks 3 are formed, opening parts 4 of the resist masks 3 are selectively filled with a protective insulating material. This can be performed by, for example, using a transfer molding method and putting the wiring substrate body 1 in which the resist masks 3 are disposed in a cavity of a metal mold in which a mold release film is arranged on a molding surface and supplying a thermosetting protective insulating material (for example, an epoxy material called a “molding compound”) to the cavity and curing the material. FIG. 1C shows protective insulating materials 5 with which the opening parts 4 (FIG. 1B) of the resist masks 3 are filled in a state of being sandwiched in mold release films 6 inside the cavity of a metal mold (not shown). Space formed by partially putting the mold release films into the opening parts 4 of the resist masks 3 by mold clamping is selectively filled with the protective insulating materials. Volume of the space can be controlled by a thickness of the mold release film, a pressure of injection or mold clamping, a heating temperature of the cavity, etc.

After the filling, the protective insulating materials 5 are cured and the metal mold with the mold release films is opened and the resist masks 3 are removed and as shown in FIG. 1D, patterned protective insulating layers 5a are obtained on the wiring layers 2 of the outermost layer of the wiring substrate body 1. The through holes 9 of the substrate body 1 are covered with the protective insulating layers 5a. The resist masks can be removed (peeled) by dissolution by a solvent or swelling by strong alkali such as caustic soda.

Then, wiring surface treatment layers 7 can be formed on the surfaces of the wiring layers 2 exposed from the protective insulating layers 5a by, for example, gold plating as shown in FIG. 1E for connection to a semiconductor chip and connection to, for example, a mounting substrate and a package in which the semiconductor chip is installed. Also, a member (a solder bump, a pin, etc.) used in connection to, for example, the mounting substrate or the semiconductor chip can be disposed. A substrate for package which is one component for semiconductor package of the invention shown in FIG. 1E comprises solder bumps 8 as a member for connection formed in a part of the opening parts of the protective insulating layers 5a.

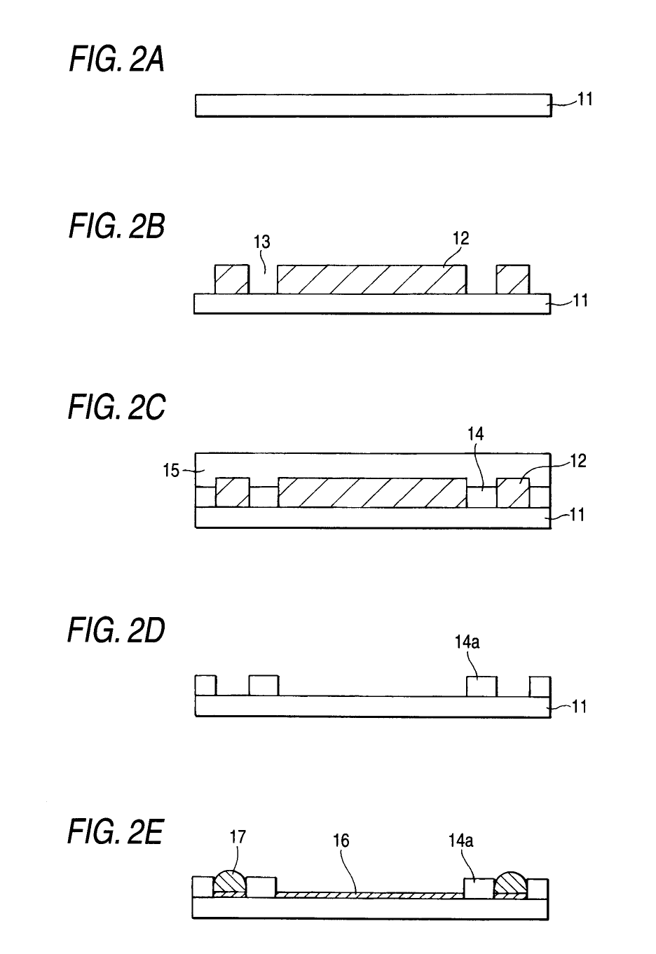

Next, a manufacturing method of a lead frame for semiconductor package will be described with reference to FIGS. 2A to 2E.

First, as shown in FIG. 2A, a lead frame body 11 is fabricated and next, as shown in FIG. 2B, a resist mask 12 is formed on the lead frame body 11. Also in this case, a resist material similar to that used in manufacture of the substrate for package described above can be used as the resist material.

After the resist mask 12 is formed, opening parts 13 of the resist mask are selectively filled with a protective insulating material. This can also be performed, for example, using a transfer molding method in a manner similar to the case of manufacture of the substrate for package described above. FIG. 2C shows a protective insulating material 14 with which the opening parts 13 (FIG. 2B) of the resist mask 12 are filled in a state of being sandwiched in a mold release film 15 inside a cavity of a metal mold (not shown). After the filled protective insulating material 14 is cured, the metal mold is opened and the mask 12 is peeled and removed and as shown in FIG. 2D, a patterned protective insulating layer 14a is obtained on the lead frame body 11.

Then, a surface treatment layer 16 can be formed on a surface of the portion exposed from the protective insulating layer 14a by, for example, gold plating as shown in FIG. 2E for connection to a semiconductor chip and connection to, for example, a mounting substrate and a package in which the semiconductor chip is installed. A member such as a solder bump used in connection to, for example, the mounting substrate or the semiconductor chip can also be disposed. A lead frame for package which is one component for semiconductor package of the invention shown in FIG. 2E comprises solder bumps 17 as a member for connection formed in a part of the opening parts of the protective insulating layer 14a.

According to the invention as can be seen in FIGS. 2A to 2E, the lead frame for package can be manufactured in a flat plate shape. In a package in which the semiconductor chip is installed in the lead frame of the flat plate shape, the whole height can be lowered, so that it can be used particularly advantageously in the case of restricting a height of mounting space.

In the example described above, the resist masks 3, 12 are used as the mask for forming the protective insulating layer, but, for example, a mask made of metal can also be used. The metal mask can be formed by plating a component body with copper etc. using a semi-additive method. The metal mask after formation of the protective insulating layer does not require alkaline liquid or solvent used in peeling of the resist mask and can easily be removed by etching.

A semiconductor chip can be installed in a component for semiconductor package according to the invention by a connection method such as wire bonding or ball grid array (BGA) connection used in fabrication of a normal semiconductor package. In some cases, other chip components such as a chip resistor or a chip capacitor together with the semiconductor chip can be installed in the component for package of the invention to fabricate the semiconductor package.

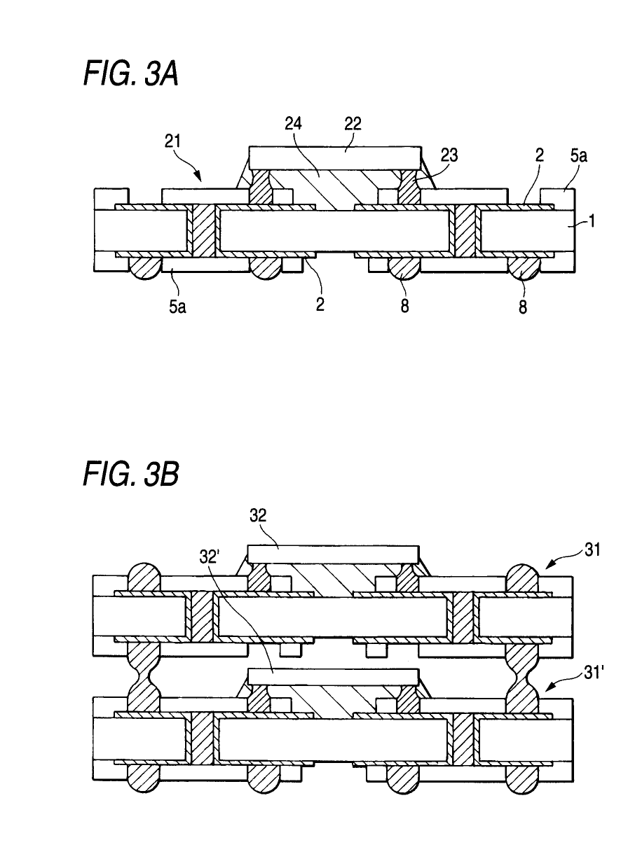

FIG. 3A shows a typical example of a semiconductor package in which a semiconductor chip 22 is installed on a substrate 21 for semiconductor package according to the invention. Connection between the chip 22 and the substrate 21 for package is made by a bonding member 23 formed by reflow solder. A gap between the chip 22 and the substrate 21 for package is filled with an underfill material 24.

FIG. 3B shows an example of forming a stack structure by stacking two semiconductor packages in which semiconductor chips 32, 32′ are respectively installed on substrates 31, 31′ for package.

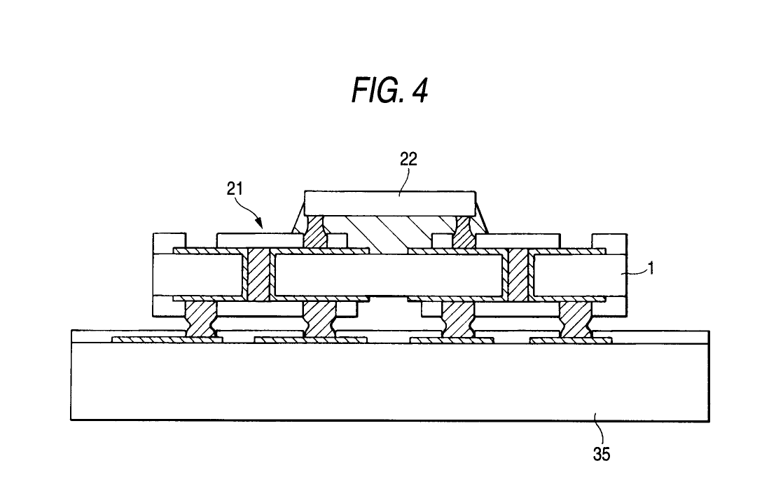

FIG. 4 shows an example in which the semiconductor package shown in FIG. 3A is mounted on a motherboard 35.

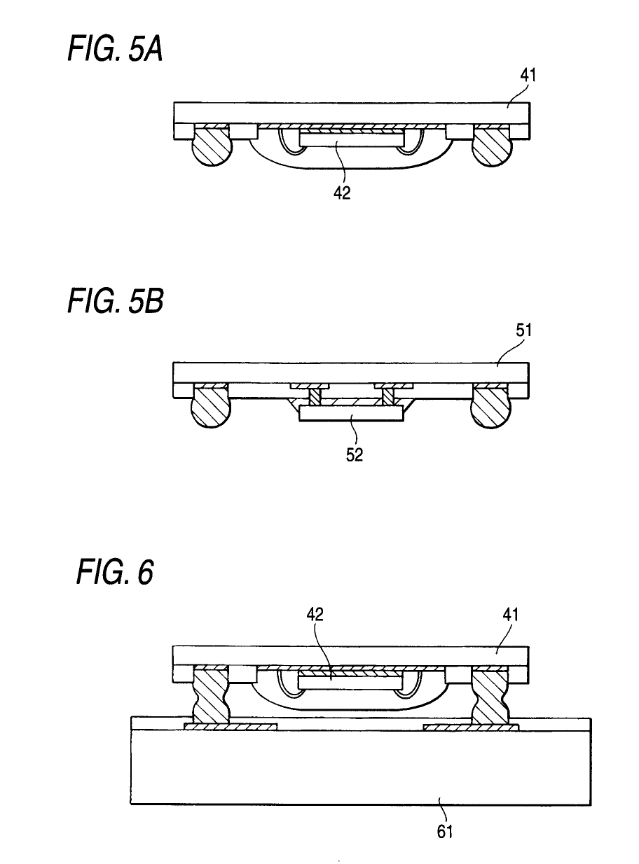

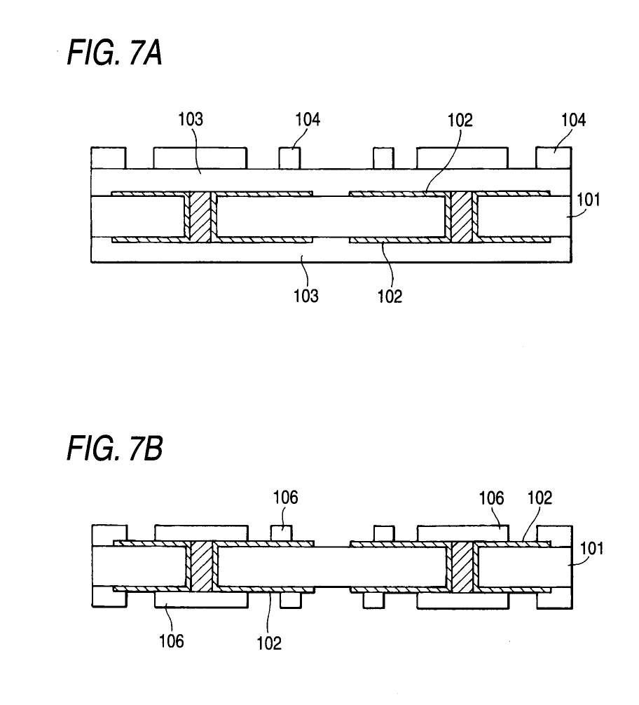

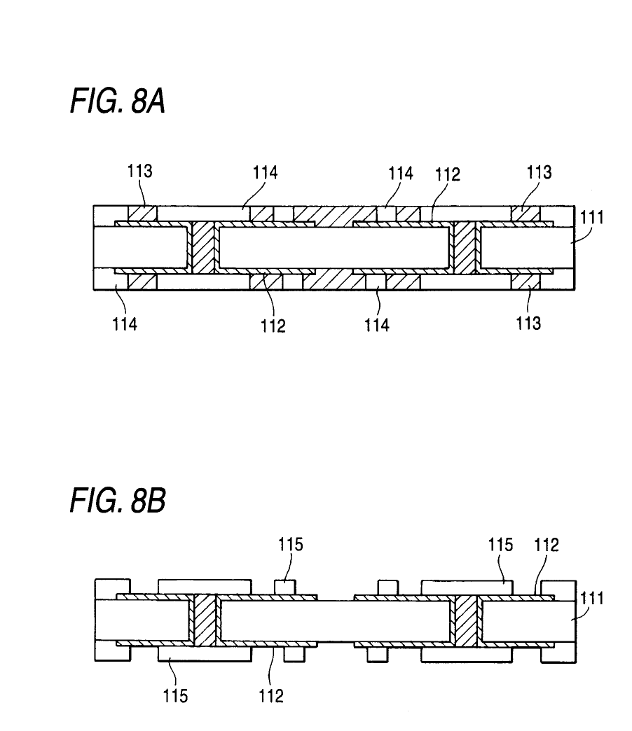

FIG. 5A shows an example of a semiconductor package in which a semiconductor chip 42 is installed on a lead frame 41 for semiconductor package according to the invention by wire bonding. FIG. 5B shows an example of a semiconductor package in which a semiconductor chip 52 is installed on a lead frame 51 for semiconductor package manufactured by a method of the invention by flip chip connection.

The packages of FIGS. 5A and 5B obtained using the lead frames for package of the invention fabricated in a flat plate shape are used particularly advantageously in the case of being mounted in space with a severe restriction on height.

FIG. 6 shows an example in which the semiconductor package shown in FIG. 5A is mounted on a motherboard 61.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

In the above-mentioned embodiment of the present invention, the thermosetting resin is used as the nonphotosensitive resin for protective insulating layer; however, the present invention is not limited to this. For example, the thermoplastic resin can be used in place of the thermosetting resin.

What is claimed is:

1. A manufacturing method of a component for semiconductor package which has a protective insulating layer on at least one surface of a component body and exposes a conductive material of the component body to an opening part of the protective insulating layer, comprising steps of:
(a) forming a mask on at least one surface of a component body, the mask having an opening part;
(b) forming a protective insulating layer by filling the opening part of the mask with a protective insulating material by a molding method using a metal mold having a mold release film; and
(c) removing the metal mold and removing the mask.

2. A manufacturing method of a component for semiconductor package as claimed in claim 1, wherein the mask is formed by a resist or a metal material.

3. A manufacturing method of a component for semiconductor package as claimed in claim 1, wherein the mask is formed by a photosensitive film.

4. A manufacturing method of a component for semiconductor package as claimed in claim 1, wherein a transfer molding method is used as the molding method.

5. A manufacturing method of a component for semiconductor package as claimed in claim 1, wherein the component body is a wiring substrate or a lead frame before the protective insulating layer is formed on at least one surface.

6. A component for semiconductor package comprising:
a component body;
a protective insulating layer formed on at least one surface of the component body and formed by a nonphotosensitive resin, the protective insulating layer has an opening part; and
an external connection terminal disposed in the opening part of the protective insulating layer.
